(19) United States
(12) Patent Application Publication
(10) Pub. No.: US 2026/0271765 A1
(43) Pub. Date: Sep. 10, 2026

(54) SEMICONDUCTOR MODULE MANUFACTURING DEVICE AND SEMICONDUCTOR MODULE MANUFACTURING METHOD

(71) Applicant: ROHM CO., LTD., Kyoto-shi (JP)

(72) Inventors: Hikaru HIIRAGI, Kyoto-shi (JP); Oji SATO, Kyoto-shi (JP); Tetsuya SHIMIZU, Kyoto-shi (JP)

(21) Appl. No.: 19/657,435

(22) Filed: Apr. 24, 2026

Related U.S. Application Data
(63) Continuation of application No. PCT/JP2024/037710, filed on Oct. 23, 2024.

(30) Foreign Application Priority Data
Nov. 2, 2023 (JP) 2023-188307

(51) Int. Cl. H10W 72/00; H10D 80/20; H10W 72/30; H10W 90/00; H10W 90/10

(52) U.S. Cl. CPC H10W 72/07178; H10W 72/07327; H10W 72/07332; H10W 72/323; H10W 72/352; H10W 72/355; H10W 90/10; H10W 90/734; H10D 80/251

(57) ABSTRACT

A semiconductor module manufacturing device includes: a first punch, a second punch, and a carrier configured to hold a support on which a semiconductor element is disposed. The first punch approaches the carrier from a first side in a first direction through relative movement, and the second punch approaches the carrier from a second side in the first direction through relative movement, the first punch and the second punch thereby performing bonding of the support and the semiconductor element. The semiconductor element is positioned on the second side in the first direction with respect to the support and includes a first ferromagnetic layer. The carrier includes a magnet section positioned on the first side in the first direction with respect to the support.

### TECHNICAL FIELD

The present disclosure relates to a semiconductor module manufacturing device and a semiconductor module manufacturing method.

### BACKGROUND ART

JP-A-2023-139229 discloses an example of a conventional semiconductor device. The semiconductor device disclosed in the document includes an insulating substrate and a semiconductor element. The semiconductor element is bonded to the insulating substrate.

### BRIEF DESCRIPTION OF THE DRAWINGS

FIG. 1 is a sectional view of a carrier of a semiconductor module manufacturing device according to a first embodiment of the present disclosure.

FIG. 2 is a sectional view illustrating a semiconductor module manufacturing method according to the first embodiment of the present disclosure.

FIG. 3 is a sectional view illustrating the semiconductor module manufacturing method according to the first embodiment of the present disclosure.

FIG. 4 is a plan view of a support and a semiconductor element in the semiconductor module manufacturing method according to the first embodiment of the present disclosure.

FIG. 5 is a partial plan view of the support and the semiconductor element in the semiconductor module manufacturing method according to the first embodiment of the present disclosure.

FIG. 6 is a partial sectional view taken along line VI-VI in FIG. 5.

FIG. 7 is an enlarged partial sectional view of the support and the semiconductor element in the semiconductor module manufacturing method according to the first embodiment of the present disclosure.

FIG. 8 is a sectional view illustrating the semiconductor module manufacturing method according to the first embodiment of the present disclosure.

FIG. 9 is a sectional view illustrating the semiconductor module manufacturing method according to the first embodiment of the present disclosure.

FIG. 10 is a sectional view illustrating the semiconductor module manufacturing method according to the first embodiment of the present disclosure.

FIG. 11 is a plan view of a semiconductor module manufactured by the semiconductor module manufacturing method according to the first embodiment of the present disclosure.

FIG. 12 is a view showing a system configuration of a vehicle incorporating a semiconductor module manufactured by the semiconductor module manufacturing method according to the first embodiment of the present disclosure.

FIG. 13 is a sectional view illustrating another semiconductor module manufacturing method according to the first embodiment of the present disclosure.

FIG. 14 is a sectional view illustrating a yet another semiconductor module manufacturing method according to the first embodiment of the present disclosure.

FIG. 15 is a sectional view of a semiconductor module manufacturing device according to a first variation of the first embodiment of the present disclosure.

FIG. 16 is a sectional view of a semiconductor module manufacturing device according to a second variation of the first embodiment of the present disclosure.

FIG. 17 is a sectional view of a semiconductor module manufacturing device according to a second embodiment of the present disclosure.

FIG. 18 is a timing chart illustrating a semiconductor module manufacturing method according to the second embodiment of the present disclosure.

FIG. 19 is a timing chart illustrating another semiconductor module manufacturing method according to the second embodiment of the present disclosure.

FIG. 20 is an enlarged partial sectional view of a support and a semiconductor element in a semiconductor module manufacturing method according to the third embodiment of the present disclosure.

### DETAILED DESCRIPTION OF EMBODIMENTS

The following specifically describes preferred embodiments of the present disclosure with reference to the drawings.

In the present disclosure, the terms such as “first”, “second”, “third”, and so on are used merely as labels and are not intended to impose a specific order or sequence on the items referred to by the terms.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B.” Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B.” Likewise, the expression “An object A is positioned on an object B” implies the situation where, unless otherwise specifically noted, “the object A is positioned on the object B, in contact with the object B”, and “the object A is positioned on the object B, with something else interposed between the object A and the object B.” Still further, the expression “An object A overlaps with an object B as viewed in a certain direction” implies the situation where, unless otherwise specifically noted, “the object A overlaps with the entirety of the object B”, and “the object A overlaps with a portion of the object B.” Still further, in the present disclosure, the expression “A surface A faces a direction B (one side or the other side in that direction) is not limited to the situation where the surface A forms an angle of 90° with the direction B, but includes the situation where the surface A is inclined with respect to the direction B.

### First Embodiment:

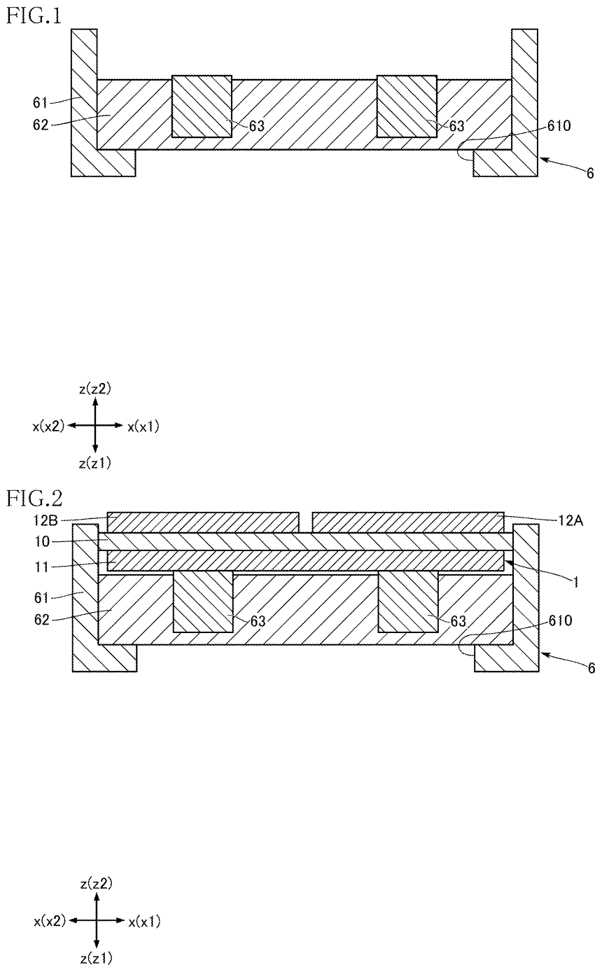

FIGS. 1 to 3, 8, and 9 show a semiconductor module manufacturing device according to a first embodiment of the present disclosure. The semiconductor module manufacturing device A1 of the present embodiment includes a first punch 7A, a second punch 7B, and a carrier 6. The semiconductor module manufacturing device A1 performs bonding of a support 1 and semiconductor elements 3A and 3B to manufacture a semiconductor module B1, which will be described later. The types of bonding that can be performed by the semiconductor module manufacturing device A1 are not particularly limited, and examples include solid-state diffusion bonding and sinter bonding. The first embodiment describes an example in which the semiconductor module manufacturing device A1 performs solid-state diffusion bonding.

Note that to perform bonding of the support 1 and the semiconductor elements 3A and 3B refers to bonding the support 1 and the semiconductor elements 3A and 3B by, for example, solid-state diffusion bonding or sinter bonding, where the support 1 and the semiconductor elements 3A and 3B are bonded either directly or with one or more other members interposed therebetween. The following description relates to an example in which the support 1 and the semiconductor elements 3A and 3B are bonded with first bonding sheets 2A and 2B interposed therebetween.

In FIGS. 1 to 3, 8, and 9, the thickness direction of the support, for example, is defined as the first direction z recited in the present disclosure. A first side in the first direction z is referred to as the z1 side, and the second side opposite the z1 side in the direction z is referred to as the z2 side. Additionally, a direction perpendicular to the first direction z is defined as the second direction x. A first side in the second direction x is referred to as the x1 side, and the second side opposite the x1 side is referred to as the x2 side. Additionally, for example, the direction perpendicular to the first direction z and the second direction x is defined as the third direction y. A first side in the third direction y is referred to as the y1 side, and the second side opposite the y1 side is referred to as the y2 side.

The carrier 6 is configured to hold the support 1 and is capable of holding the support 1 on which the semiconductor elements 3A and 3B are placed. In this example, the carrier 6 may hold the support 1 on which the first bonding sheets 2A and 2B and the semiconductor elements 3A and 3B are placed.

The carrier 6 includes one or more magnet sections 63. The carrier 6 may additionally include a frame portion 61 and a support portion 62. The frame portion 61 serves as the base of the carrier 6. The frame portion 61 may be made of a non-magnetic material, such as austenitic stainless steel, aluminum, or resin. In the illustrated example, the frame portion 61 has an opening 610 that extends through the frame portion in the first direction z. The support portion 62 is positioned inside the frame portion 61 and, in the illustrated example, closes off the opening 610. The support portion 62 may be made of a non-magnetic material, such as austenitic stainless steel, aluminum, or resin.

The one or more magnet sections 63 may be supported by the frame portion 61 or the support portion 62. In the illustrated example, the magnet sections 63 are supported by the support portion 62. The magnet sections 63 exert a magnetic force that is appropriate for a semiconductor module manufacturing method, which will be described later. The number of magnet sections 63 is not particularly limited and may comprise a single magnet section or a plurality of magnet sections. In the illustrated example, each magnet section 63 is positioned to overlap with one of the semiconductor elements 3A and 3B as viewed in the first direction z. When four semiconductor elements 3A and four semiconductor elements 3B are disposed on the support 1 as shown in FIG. 4, the carrier 6 may include eight magnet sections 63 in total.

Each magnet section 63 may be a permanent magnet or an electromagnet. In the present embodiment, the magnet sections 63 are permanent magnets. The manner in which the magnet sections 63 are supported by the frame portion 61 or the support portion 62 is not particularly limited. In the illustrated example, each magnet section 63 is exposed from the support portion 62 toward the z2 side in the first direction z and slightly protrudes from the support portion 62 toward the z2 side in the first direction z.

The first punch 7A approaches the carrier 6 from the z1 side in the first direction z through relative movement to perform solid-state diffusion bonding of the support 1 and the semiconductor elements 3A and 3B. The number, material, shape, and position of the first punch 7A are not particularly limited. In the illustrated example, a single first punch 7A is included. The first punch 7A is sized, shaped, and positioned to overlap with the semiconductor elements 3A and 3B as viewed in the first direction z. The first punch 7A may be made of a non-magnetic metal, such as austenitic stainless steel or aluminum.

In the illustrated example, the first punch 7A may be supported on a base 70. The base 70 is, for example, a foundation made of metal. Alternatively, the first punch 7A may be movable in the first direction z.

The base 70 may be provided with a plurality of pins 71 as appropriate. The pins 71 may be components, such as springs, capable of elastically extending and contracting in the first direction z. Alternatively, the pins 71 may be movable in the first direction z.

The second punch 7B approaches the carrier 6 from the z2 side in the first direction z through relative movement to perform solid-state diffusion bonding of the support 1 and the semiconductor elements 3A and 3B. The number, material, shape, and position of the second punch 7B are not particularly limited. In the illustrated example, eight second punches 7B are included, which is equal to the number of the semiconductor elements 3A and 3B. Each of the eight second punches 7B is sized, shaped, and positioned to overlap with a corresponding one of the four semiconductor elements 3A and the four semiconductor elements 3B. The second punches 7B may be made of non-magnetic metal, such as austenitic stainless steel or aluminum.

The second punch 7B may be movable in the first direction z by a drive source, such as hydraulic or pneumatic pressure. Alternatively, the second punch 7B may be fixed in position in the first direction z, while the first punch 7A may be movable in the first direction z.

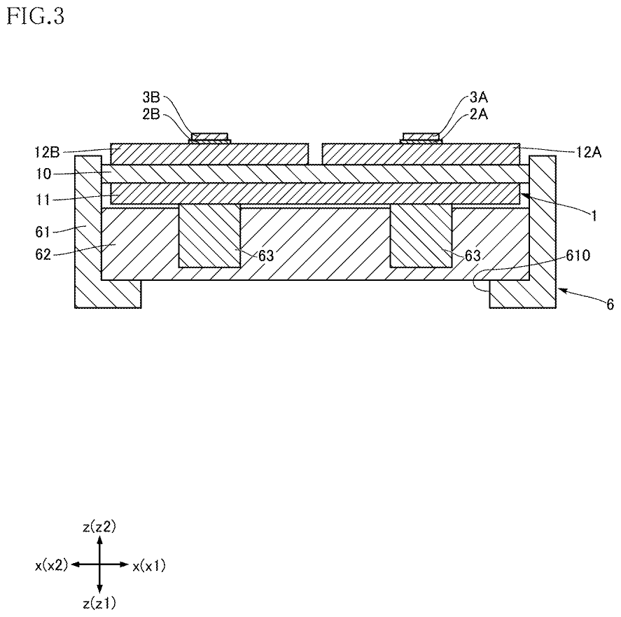

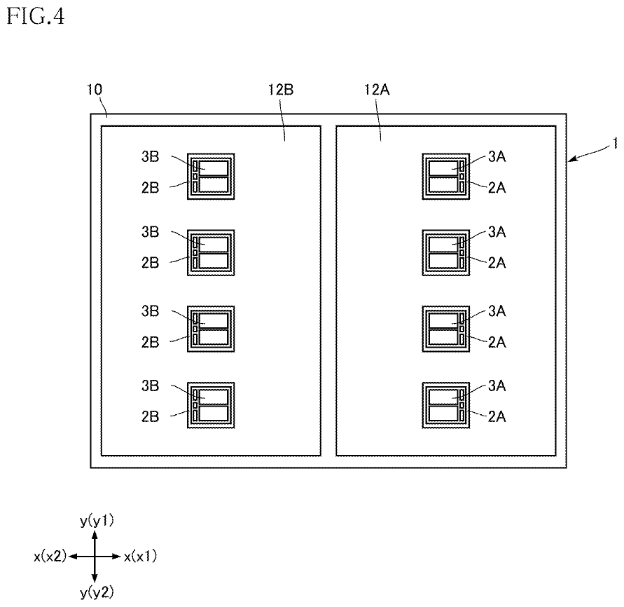

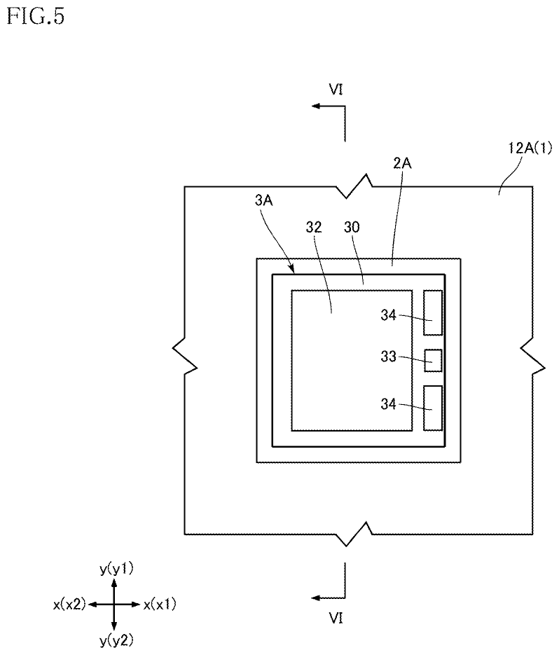

With reference now to FIGS. 3 to 7, the following describes the support 1, the semiconductor elements 3A and 3B, and the first bonding sheets 2A and 2B.

The support 1 includes an insulating layer 10, a first metal layer 11, a second metal layer 12A, and a second metal layer 12B.

The insulating layer 10 may be a plate-shaped insulating member and may contain ceramic. The first metal layer 11 is stacked on the insulating layer 10 from the z1 side in the first direction z. The first metal layer 11 contains metal, such as copper (Cu). The second metal layer 12A is stacked on the insulating layer 10 from the z2 side in the first direction z and is offset toward the x1 side in the second direction x. The second metal layer 12B is disposed on the insulating layer 10 from the z2 side in the first direction z and is offset toward the x2 side in the second direction x. The second metal layers 12A and 12B are spaced apart from each other and each contain metal, such as copper (Cu). The insulating layer 10, the first metal layer 11, and the second metal layers 12A and 12B may form a direct bonded copper (DBC) substrate or an active metal brazing (AMB) substrate.

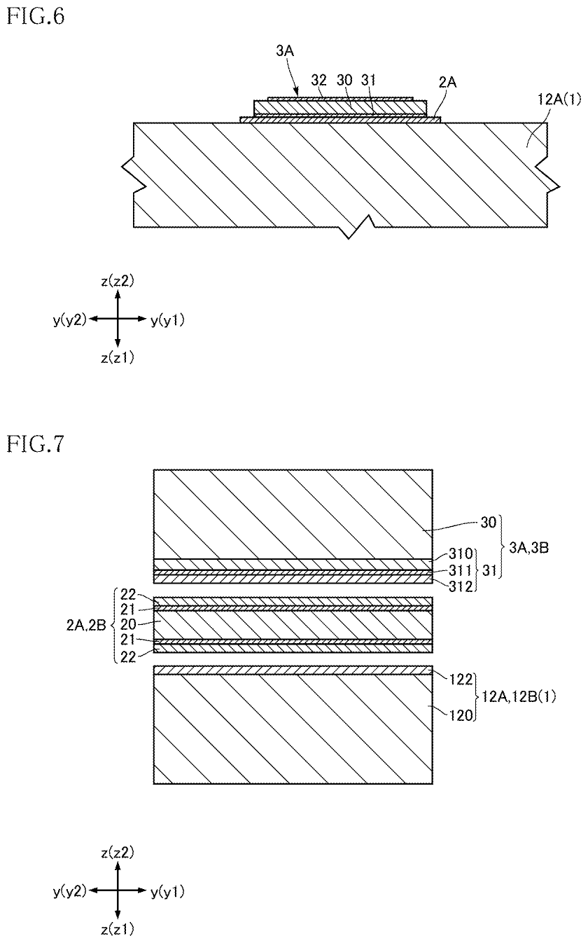

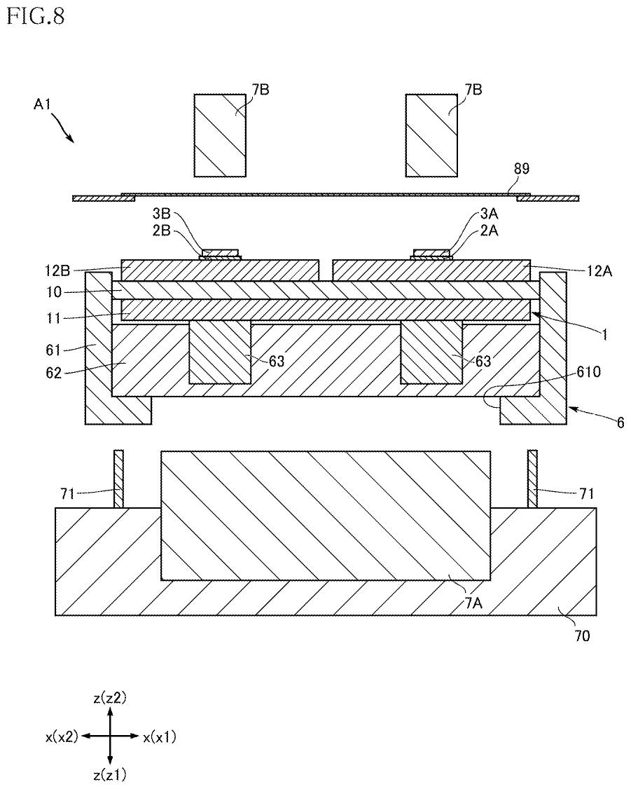

As shown in FIG. 7, each of the second metal layers 12A and 12B includes a main body layer 120 and a third bonding layer 122. The main body layer 120 contains metal, such as copper (Cu). The third bonding layer 122 is to be bonded by solid-state diffusion bonding and may contain silver (Ag). The third bonding layer 122 may have a thickness between 0.1 μm and 10 μm, for example.

Each of the semiconductor elements 3A and 3B may be made of a semiconductor material primarily composed of silicon carbide (SiC). The semiconductor material, however, is not limited to a SiC-based material, and other examples include silicon (Si), gallium arsenide (GaAs), and gallium nitride (GaN). In the present embodiment, the semiconductor elements 3A and 3B may be metal-oxide-semiconductor field effect transistors (MOSFETs). The semiconductor elements 3A and 3B are not particularly limited to the MOSFETS, and may alternatively be field effect transistors, such as metal-insulator-semiconductor FETs (MISFETs), bipolar transistors, such as insulated gate bipolar transistors (IGBTs), IC chips, such as LSIs, diodes, or capacitors.

In the present embodiment, each of the semiconductor elements 3A and 3B includes an element body 30, a drain electrode 31, a source electrode 32, a gate electrode 33, and a source-sense electrode 34. The element body 30 is made of the semiconductor material described above. The drain electrode 31 is disposed on the z1 side in the first direction z with respect to the element body 30. The source electrode 32, the gate electrode 33, and the source-sense electrode 34 are disposed on the z2 side in the first direction z with respect to the element body 30.

As shown in FIG. 7, the drain electrode 31 may include a main body layer 310, a first ferromagnetic layer 311, and a first bonding layer 312. The main body layer 310 forms the body of the drain electrode 31 and may contain metal, such as copper (Cu) or aluminum (Al). The first bonding layer 312 is to be bonded by solid-state diffusion bonding and may contain silver (Ag). The first ferromagnetic layer 311 is made of ferromagnetic metal, such as nickel (Ni), iron (Fe), or cobalt (Co). The first ferromagnetic layer 311 may be positioned between the main body layer 310 and the first bonding layer 312. Additionally or alternatively to the drain electrode 31, the source electrode 32, the gate electrode 33, and the source-sense electrode 34 may include a ferromagnetic layer similar to the first ferromagnetic layer 311. The main body layer 310 may have a thickness between 0.01 μm and 5 μm, for example. The first ferromagnetic layer 311 may have a thickness between 0.1 μm and 10 μm, for example. The first bonding layer 312 may have a thickness between 0.01μm and 5μm, for example. The specific configuration of the first ferromagnetic layer according to the present disclosure is not particularly limited. In the semiconductor elements 3A and 3B, at least one of the drain electrode 31, the source electrode 32, the gate electrode 33, and the source-sense electrode 34 may include a first ferromagnetic layer.

The first bonding sheet 2A is disposed between the second metal layer 12A of the support 1 and the drain electrode 31 of the semiconductor element 3A. The first bonding sheet 2A is for electrically bonding the semiconductor element 3A and the second metal layer 12A by, for example, solid-state diffusion bonding. The first bonding sheet 2B is disposed between the second metal layer 12B of the support 1 and the drain electrode 31 of the semiconductor element 3B. The first bonding sheet 2B is for electrically bonding the semiconductor element 3B and the second metal layer 12B by, for example, solid-state diffusion bonding. The specific configuration of the first bonding sheets 2A and 2B is not particularly limited.

As shown in FIG. 7, each of the first bonding sheets 2A and 2B may include a main body layer 20, two second ferromagnetic layers 21, and two third bonding layers 22. The main body layer 20 is a base layer containing aluminum (Al), for example. The two third bonding layers 22 are disposed on opposite sides of the main body layer 20 in the first direction z. The third bonding layers 22 are to be bonded by solid-state diffusion bonding and may contain silver (Ag). Each of the two second ferromagnetic layers 21 is disposed between the main body layer 20 and one of the two third bonding layers 22. The second ferromagnetic layers 21 are made of ferromagnetic metal, such as nickel (Ni), iron (Fe), or cobalt (Co). The main body layer 20 may have a thickness between 50 μm and 500 μm, for example. The second ferromagnetic layers 21 may have a thickness between 0.1 μm and 10 μm, for example. The third bonding layers 22 may have a thickness between 0.1 μm and 10 μm, for example.

The following describes a semiconductor module manufacturing method using the semiconductor module manufacturing device A1.

The method begins with preparing the carrier 6 as shown in FIG. 1.

Subsequently, as shown in FIG. 2, the support 1 is placed and held by the carrier 6. Here, the first metal layer 11 is positioned on the z1 side in the first direction z, facing the support portion 62 and the magnet section 63. In the illustrated example, the first metal layer 11 is in contact with the magnet section 63.

Subsequently, as shown in FIG. 3, the first bonding sheet 2A is disposed on the second metal layer 12A, and the first bonding sheet 2B is disposed on the second metal layer 12B. In this state, the magnetic force of the magnet sections 63 acts on the respective second ferromagnetic layers 21 of the first bonding sheets 2A and 2B. Additionally, a semiconductor element 3A is disposed on the first bonding sheet 2A, and a semiconductor element 3B is disposed on the first bonding sheet 2B. In this state, the magnetic force of the magnet sections 63 acts on the respective first ferromagnetic layers 311 of the semiconductor elements 3A and 3B.

In this example, as shown in FIG. 4, four first bonding sheets 2A and four semiconductor elements 3A are disposed on the second metal layer 12A, and four first bonding sheets 2B and four semiconductor elements 3B are disposed on the second metal layer 12B. These numbers and arrangements are exemplary and are not intended to be limiting. For convenience, FIG. 7 shows a clearance between the second metal layer 12A or 12B and the first bonding sheet 2A or 2B, but they are actually in contact in the mounted state. FIG. 7 also shows a clearance between the first bonding sheet 2A or 2B and the semiconductor element 3A or 3B, but they are actually in contact in the mounted state.

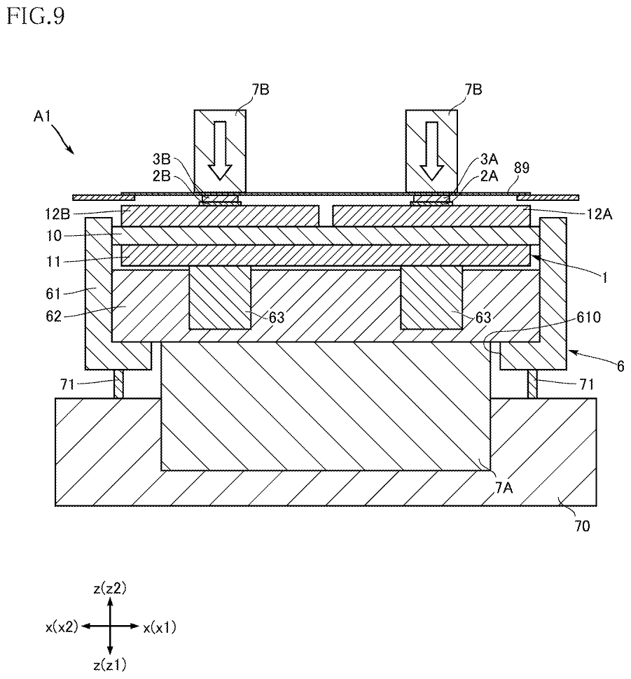

Subsequently, as shown in FIG. 8, the carrier 6 that holds the support 1 is placed between the first punch 7A and the second punches 7B. In the illustrated example, a protective sheet 89 is disposed between the semiconductor elements 3A and 3B and the second punch 7B to protect the semiconductor elements 3A and 3B. Note, however, that the manufacturing method may be carried out without the protective sheet 89.

Subsequently, as shown in FIG. 9, the first punch 7A and the second punch 7B are moved relative to the carrier 6 such that the first punch 7A approaches the carrier 6 from the z1 side in the first direction z, and the second punch 7B approaches the carrier 6 from the z2 side in the first direction z. As a result, the first punch 7A and the second punch 7B apply a pressing force to the carrier 6, the support 1, the first bonding sheets 2A and 2B and the semiconductor elements 3A and 3B. This causes solid-state diffusion bonding between the support 1 and the semiconductor elements 3A and 3B. In the illustrated example, the support 1 is bonded to the semiconductor elements 3A and 3B respectively via the first bonding sheets 2A and 2B interposed between them.

In the illustrated example, the first punch 7A is fixed in position in the first direction z, while the second punch 7B moves in the first direction z from the z2 side toward the z1 side. In this way, the first punch 7A and the second punch 7B accroach the carrier 6 through relative movement. In this state, the pins 71 are pressed against the frame portion 61 of the carrier 6 and thus in the contracted state in the first direction z.

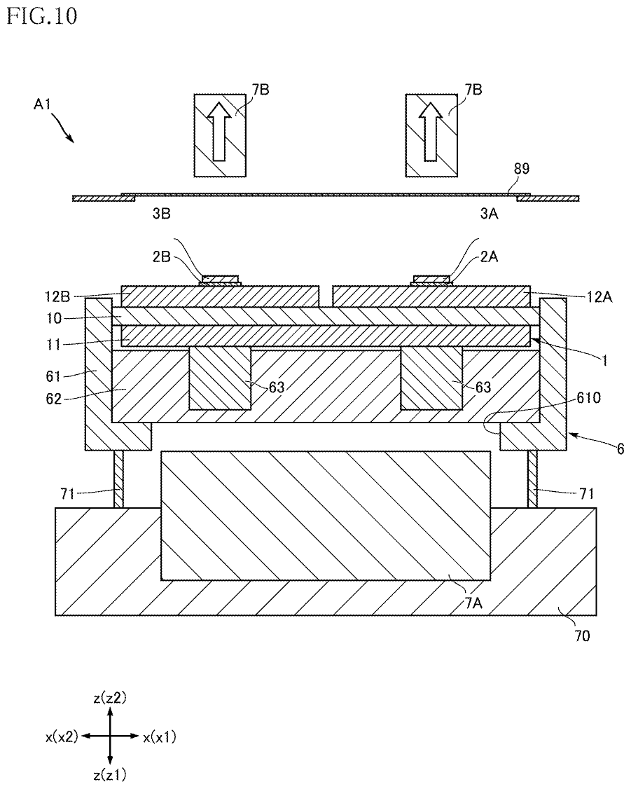

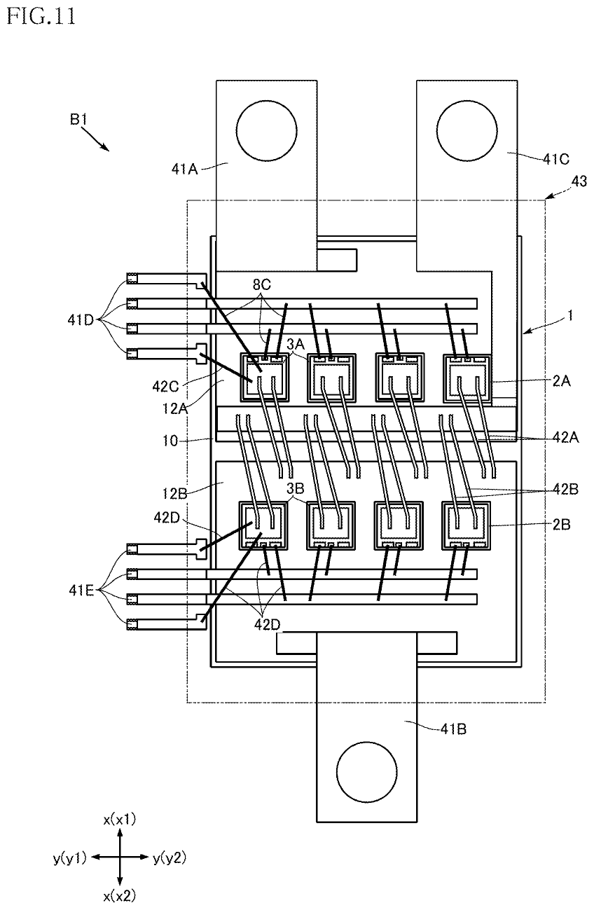

Subsequently, as shown in FIG. 10, the second punch 7B is retracted to the position on the z1 side in the first direction z. In this state, the pins 71 extend to their original lengths due to an elastic force or a force from the drive source.

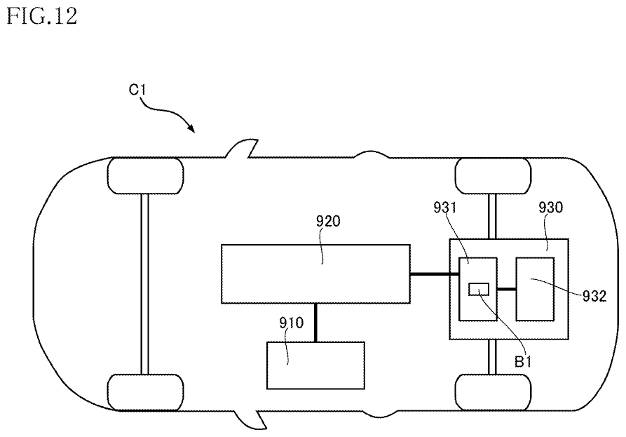

Subsequently, the components described below are sequentially attached to form the semiconductor module B1 shown in FIG. 11.

FIG. 11 shows the semiconductor module B1, which is manufactured using the semiconductor module manufacturing device A1 and the semiconductor module manufacturing method according to the first embodiment of the present disclosure. The semiconductor module B1 includes a support 1, one or more semiconductor elements 3A, and one or more first bonding sheets 2A. In the present embodiment, the semiconductor module B1 additionally includes one or more semiconductor elements 3B, one or more first bonding sheets 2B, a positive input terminal 41A, an output terminal 41B, a negative input terminal 41C, a plurality of control terminals 41D, a plurality of control terminals 41E, a plurality of first wires 42A, a plurality of second wires 42B, a plurality of third wires 42C, a plurality of fourth wires 42D, and a sealing resin 43.

The number of the semiconductor elements 3A and the number of the semiconductor element 3B are not particularly limited. In the present embodiment, the semiconductor module B1 includes a plurality of semiconductor elements 3A and a plurality of semiconductor elements 3B. The number of the first bonding sheets 2A and the number of the first bonding sheets 2B are not particularly limited. In the present embodiment, the semiconductor module B1 includes a plurality of first bonding sheets 2A and a plurality of first bonding sheets 2B.

The semiconductor module B1 is not limited to any particular application. The semiconductor module B1 includes a half-bridge circuit that is formed by the semiconductor elements 3A forming an upper arm and the semiconductor elements 3B forming a lower arm. For example, the semiconductor module B1 constitutes an inverter that converts DC power into AC power to supply power to a drive source, such as a motor. While the present embodiment illustrates the semiconductor module B1 including one half-bridge circuit, in another example, the semiconductor module B1 may include three half-bridge circuits to supply power to a three-phase AC motor.

The semiconductor elements 3B are electrically bonded to the second metal layer 12B via the first bonding sheets 2B. In the present embodiment, the drain electrodes 31 of the semiconductor elements 3B are electrically bonded to the second metal layer 12B via the first bonding sheets 2B. The shape of the first bonding sheets 2B is not particularly limited, and is rectangular in the illustrated example. The first bonding sheets 2B may have the same or a different configuration from that of the first bonding sheets 2A.

The positive input terminal 41A is for connection to the positive terminal of a DC power supply. The positive input terminal 41A is electrically bonded to the second metal layer 12A.

The output terminal 41B is for connection to a load, such as a motor. The output terminal 41B is electrically bonded to the second metal layer 12B.

The negative input terminal 41C is for connection to the negative terminal of the DC power supply. The negative input terminal 41C is electrically connected to the source electrodes 32, for example, of the semiconductor elements 3B via the second wires 42B. The second wires 42B contain metal, such as copper (Cu), aluminum (Al), or gold (Au).

The source electrodes 32, for example, of the semiconductor elements 3A are electrically connected to the third metal layer 13B via the first wires 42A. The first wires 42A contain metal, such as copper (Cu), aluminum (Al), or gold (Au).

The control terminals 41D are for control of the semiconductor elements 3A. The control terminals 41D are electrically connected to the gate electrodes 33 or the source-sense electrodes 34, for example, of the semiconductor elements 3A via the third wires 42C. The third wires 42C contain metal, such as copper (Cu), aluminum (Al), or gold (Au).

The control terminals 41E are for control of the semiconductor elements 3B. The control terminals 41E are electrically connected to the gate electrodes 33 or the source-sense electrodes 34, for example, of the semiconductor elements 3B via the fourth wires 42D. The fourth wires 42D contain metal, such as copper (Cu), aluminum (Al), or gold (Au).

The sealing resin 43 covers a portion of the support 1, the semiconductor elements 3A, the semiconductor elements 3B, and other appropriate components or portions thereof. The positive input terminal 41A, the output terminal 41B, the negative input terminal 41C, and the control terminals 41D and 41E each have a portion protruding from the sealing resin 43.

With reference to FIG. 12, the following describes a vehicle C1 incorporating the semiconductor module B1. The vehicle C1 is an electric vehicle (EV), for example.

As shown in FIG. 12, the vehicle C1 includes an on-board charger 910, a storage battery 920, and a drive system 930. The on-board charger 910 wirelessly receives power from an outdoor power supply facility (not shown). Alternatively, the on-board charger 910 may receive power via a wired connection. The on-board charger 910 includes a step-up DC-DC converter. The converter increases the voltage inputted to the on-board charger 910 and supplies the resulting power to the storage battery 920. The voltage is increased to 600 V, for example.

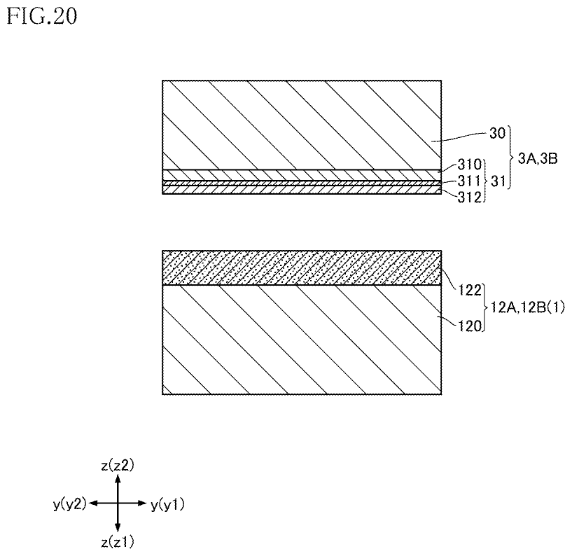

The drive system 930 propels the vehicle C1. The drive system 930 includes an inverter 931 and a drive source 932. The semiconductor module B1 forms part of the inverter 931. The power stored in the storage battery 920 is supplied to the inverter 931. The power supplied from the storage battery 920 to the inverter 931 is DC power. In an example different from the power system shown in FIG. 20, an additional step-up DC-DC converter may be provided between the storage battery 920 and the inverter 931. The inverter 931 converts the DC power to AC power. The inverter 931, which includes the semiconductor module B1, is electrically connected to the drive source 932.

The drive source 932 includes an AC motor and a transmission. When AC power converted by the inverter 931 is supplied to the drive source 932, the AC motor rotates and its rotation is transmitted to the transmission. The transmission reduces the rotational speed transmitted from the AC motor as needed, and rotates the drive shaft of the vehicle C1. As a result, the vehicle C1 is driven. While the vehicle C1 is driving, the rotational speed of the AC motor needs to be adjusted based on the position of the accelerator pedal and other relevant information. The semiconductor module B1 in the inverter 931 is necessary for outputting AC power with a frequency appropriately adjusted to match the target rotational speed of the AC motor.

The following describes effects of the semiconductor module manufacturing device A1 and of the semiconductor module manufacturing method that uses the semiconductor module manufacturing device A1.

As shown in FIGS. 3, 8, and 9, the carrier 6 includes a magnet section 63. The magnetic force from the magnet section 63 pulls the first ferromagnetic layers 311 of the semiconductor elements 3A and 3B toward the z1 side in the first direction z. As a result, the semiconductor elements 3A and 3B are more firmly positioned on the support 1. This serves to prevent misalignment of the semiconductor elements 3A and 3B during placement of the semiconductor elements 3A and 3B or during transport of the carrier 6, thereby allowing more accurate bonding of the semiconductor elements 3A and 3B.

The magnet section 63 is composed of a permanent magnet. Consequently, the configuration of the carrier 6 is not unnecessarily complex.

The first punch 7A is made of a non-magnetic material, so that the carrier 6 and the first punch 7A are not excessively attracted to each other by the magnetic force of the magnet section 63.

The second punch 7B is made of a non-magnetic material, so that the carrier 6 and the second punch 7B are not excessively attracted to each other by the magnetic force of the magnet section 63.

The magnet section 63 is positioned to overlap with the semiconductor elements 3A and 3B as viewed in the first direction z. This arrangement ensures that the magnetic force of the magnet section 63 is effectively applied to the first ferromagnetic layers 311 of the semiconductor elements 3A and 3B.

The first bonding sheets 2A and 2B promote solid-state diffusion bonding between the second metal layers 12A and 12B and the semiconductor elements 3A and 3B.

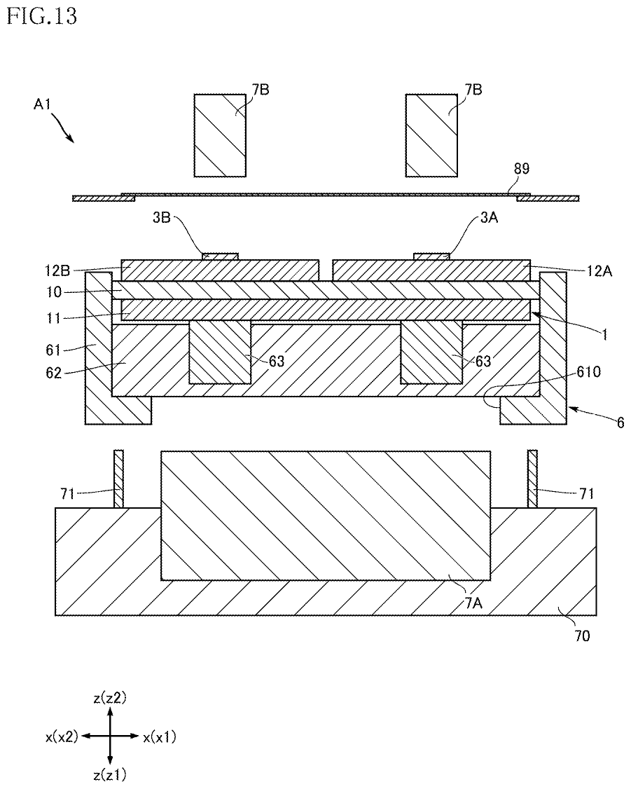

FIGS. 13 to 20 show variations and other embodiments of the present disclosure. In these figures, elements that are identical or similar to those of the above embodiment are indicated by the same reference numerals. Note that configurations of elements and components employed in the embodiments and variations may be combined in any manner, provided that no technical inconsistencies arise.

FIG. 13 shows a variation of the semiconductor module manufacturing method using the semiconductor module manufacturing device A1. In this variation, the first bonding sheets 2A and 2B are not provided between the second metal layers 12A and 12B and the semiconductor elements 3A and 3B. The second metal layers 12A, 12B and the semiconductor elements 3A and 3B are directly bonded by solid-state diffusion bonding.

This variation also ensures appropriate bonding of the semiconductor elements 3A and 3B. As can be seen from this variation, the semiconductor module manufacturing method using the semiconductor module manufacturing device A1 can be implemented with or without the use of the first bonding sheets 2A and 2B.

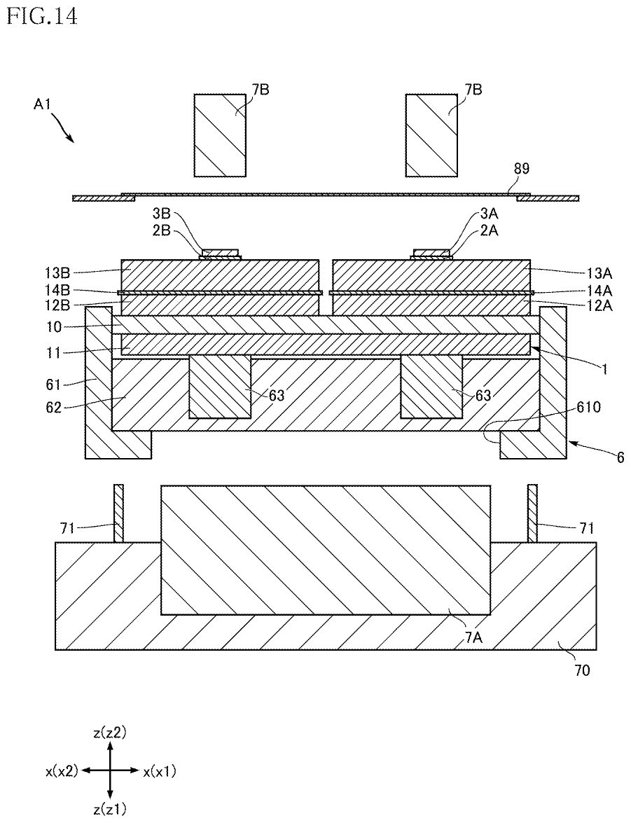

FIG. 14 shows another variation of the semiconductor module manufacturing method using the semiconductor module manufacturing device A1. In this variation, the second bonding sheets 14A and 14B and third metal layers 13A and 13B are placed over the second metal layers 12A and 12B. The first bonding sheets 2A, and 2B are placed on the third metal layers 13A and 13B.

The third metal layer 13A is bonded to the second metal layer 12A via the second bonding sheet 14A. The third metal layer 13A may include a main body layer containing metal, such as copper (Cu), and a bonding layer similar to the third bonding layer 122 described above. The second bonding sheet 14A enables solid-state diffusion bonding between the second metal layer 12A and the second bonding sheet 14A. The specific configuration of the second bonding sheet 14A is not particularly limited, and may have the same configuration as that of the first bonding sheets 2A.

The third metal layer 13B is bonded to the second metal layer 12B via the second bonding sheet 14B. The third metal layer 13B may include a main body layer containing metal, such as copper (Cu), and a bonding layer similar to the third bonding layer 122 described above. The second bonding sheet 14B enables solid-state diffusion bonding between the second metal layer 12B and the second bonding sheet 14B. The specific configuration of the second bonding sheet 14B is not particularly limited, and may have the same configuration as that of the first bonding sheets 2B.

This variation also ensures appropriate bonding of the semiconductor elements 3A and 3B. As can be seen from this variation, the semiconductor module manufacturing method using the semiconductor module manufacturing device A1 can be implemented with or without the use of the second bonding sheets 14A and 14B and the third metal layers 13A and 13B.

### First Variation of First Embodiment:

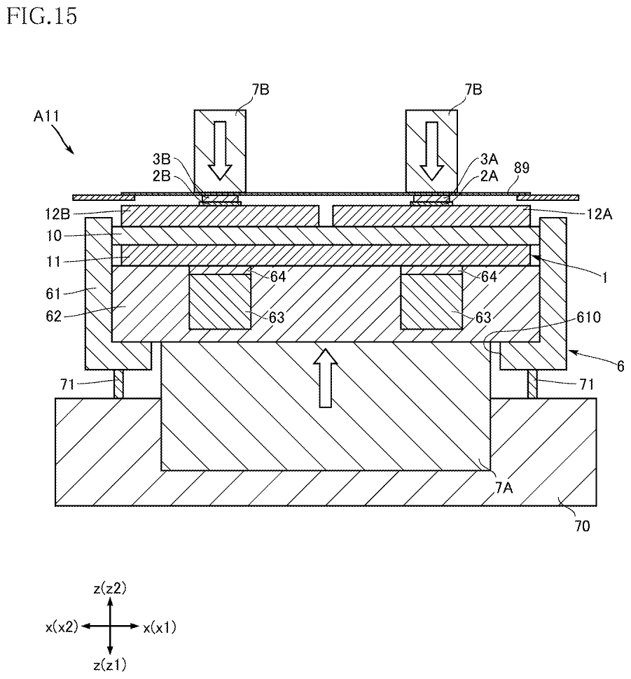

FIG. 15 shows a first variation of the semiconductor module manufacturing device A1. The semiconductor module manufacturing device A11 of this variation includes a carrier 6 having a non-magnetic cover 64.

The non-magnetic cover 64 is disposed on the z2 side in the first direction z with respect to the magnet section 63 and covers the magnet section 63 from the z2 side in the first direction z. The non-magnetic cover 64 may be made of a non-magnetic material, such as austenitic stainless steel, aluminum, or resin. In the variation, the non-magnetic cover 64 is in contact with the first metal layer 11 of the support 1, and thus the magnet section 63 is not in contact with the first metal layer 11.

This variation also ensures appropriate bonding of the semiconductor elements 3A and 3B. As can be seen from this variation, the configuration of the magnet section 63 of the carrier 6 is not particularly limited.

### Second Variation of First Embodiment:

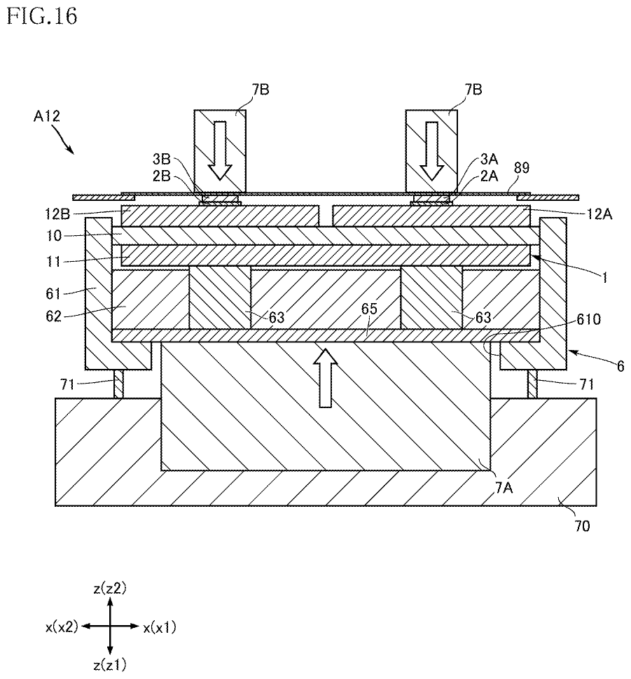

FIG. 16 shows a second variation of the semiconductor module manufacturing device A1. The semiconductor module manufacturing device A12 of this variation includes a carrier 6 having a ferromagnetic cover 65.

The ferromagnetic cover 65 is disposed on the z1 side in the first direction z with respect to the magnet section 63 and covers the magnet section 63 from the z1 side in the first direction z. The magnet section 63 is made of a ferromagnetic material, such as iron (Fe), nickel (Ni), or cobalt (Co).

This variation also ensures appropriate bonding of the semiconductor elements 3A and 3B. The provision of the ferromagnetic cover 65 serves to reduce the magnetic force of the magnet section 63 acting on the z1 side in the first direction z. This suppresses the effect of the magnetic force on the first punch 7A or other components that positioned on the z1 side in the first direction z with respect to the magnet section 63. As can be seen from this variation, the configuration of the magnet section 63 of the carrier 6 is not particularly limited.

### Second Embodiment:

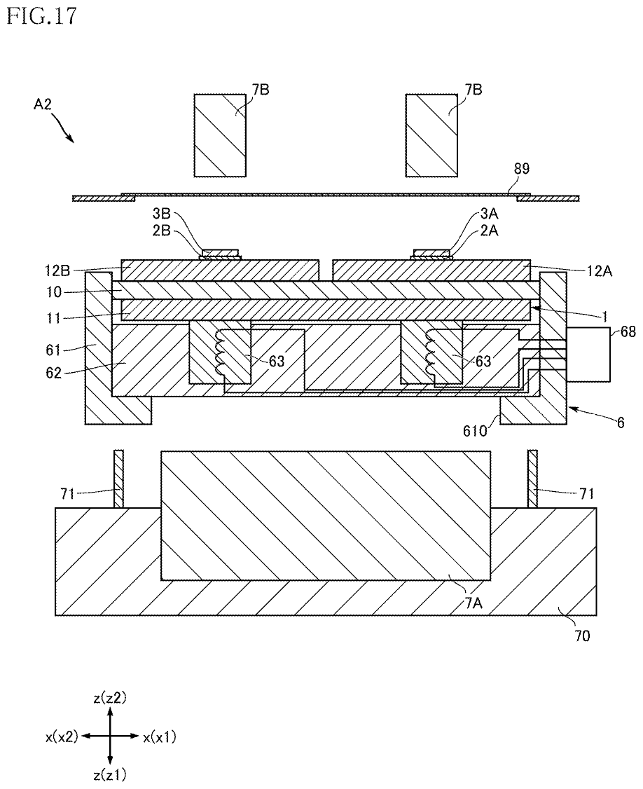

FIG. 17 shows a semiconductor module manufacturing device according to a second embodiment of the present disclosure. The semiconductor module manufacturing device A2 of the present embodiment includes a magnet section 63 constituted by an electromagnet.

A magnet controller 68 is connected to the magnet section 63. The magnet controller 68 controls on and off of the magnet section 63, which is an electromagnet, and also controls the magnitude of the current supplied to the magnet section 63. The magnet controller 68 may be attached to the carrier 6 or may be spaced apart from the carrier 6.

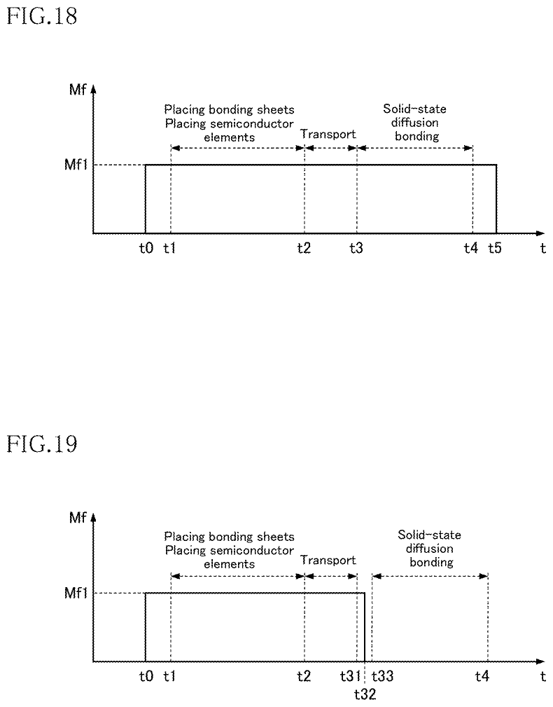

FIG. 18 shows an example of the operation of the semiconductor module manufacturing device A2. The horizontal axis represents time, whereas the vertical axis represents the magnetic force Mf of the magnet section 63. At time t0, the magnet section 63 is energized, and magnetic force Mf1 is generated. At time t1, placement of the first bonding sheets 2A and 2B and the semiconductor elements 3A and 3B onto the support 1 begins. During the period from time t2 to t3, the carrier 6 is transported to a position between the first punch 7A and the second punch 7B. At time t3, solid-state diffusion bonding is performed by the first punch 7A and the second punch 7B. After the solid-state diffusion bonding is completed at time t4, the magnet section 63 is de-energized at time t5, and thus the magnetic force Mf of the magnet section 63 becomes zero.

FIG. 19 shows another example of the operation of the semiconductor module manufacturing device A2. In this example, after the transport of the carrier 6 is completed at time t31, the magnet section 63 is de-energized at time t32, so that the magnetic force Mf of the magnet section 63 becomes zero. Subsequently, at time t33, solid-state diffusion bonding begins.

The present embodiment also ensures appropriate bonding of the semiconductor elements 3A and 3B. Being constituted as an electromagnet, the magnet section 63 can be selectively energized to generate magnetic force. In the example operation shown in FIG. 18, the magnetic force Mf1 of the magnet section 63 is maintained during the period from time t1 to t4. This more reliably prevents misalignment of the first bonding sheets 2A and 2B and the semiconductor elements 3A and 3B. In the operation example shown in FIG. 19, in contrast, the magnetic force Mf of the magnet section 63 is dropped to zero after the transport of the carrier 6 is completed at time t31. This still prevents misalignment of the first bonding sheets 2A and 2B, the semiconductor elements 3A and 3B, and others, during placement of the first bonding sheets 2A and 2B and the semiconductor elements 3A and 3B, and also during transport of the carrier 6.

FIG. 20 illustrates a semiconductor module manufacturing method according to a third embodiment of the present disclosure. In the present embodiment, the semiconductor elements 3A and 3B and the support 1 are bonded by sinter bonding.

Each of the second metal layers 12A and 12B includes a main body layer 120 and a third bonding layer 122. The third bonding layer 122 contains metal that enables sinter bonding. The metal that enables sinter bonding is not particularly limited, and examples thereof include silver (Ag) and copper (Cu). The first bonding layer 312 may also contain the same metal that enables sinter bonding as the metal contained in the third bonding layer 122.

The third bonding layer 122 may be formed by applying a paste containing the metal that enables sinter bonding to the main body layer 120, followed by drying. The thickness of the third bonding layer 122 is not particularly limited and may be between 10 μm and 200 μm, for example.

In the present embodiment, a semiconductor module manufacturing device similar to the semiconductor module manufacturing device A1 may be used to bond the semiconductor elements 3A and 3B and the support 1. This semiconductor module manufacturing device permits appropriate settings for sinter bonding, including pressing force and temperature.

The present embodiment also ensures appropriate bonding of the semiconductor elements 3A and 3B. In addition, the magnetic force of the magnet section 63 presses the semiconductor elements 3A and 3B against the third bonding layer 122, thereby enabling omission of processes such as temporarily pressure-bonding the semiconductor elements 3A and 3B to the third bonding layers 122 of the support 1 prior to sinter bonding.

The semiconductor module manufacturing device and the semiconductor module manufacturing method according to the present disclosure are not limited to the embodiments described above. Various modifications in design may be made freely in the specific structure of each part of the semiconductor module manufacturing device and the semiconductor module manufacturing method according to the present disclosure. The present disclosure includes embodiments described in the following clauses.

### Clause 1

A semiconductor module manufacturing device (A1) comprising:

a first punch (7A);

a second punch (7B); and

a carrier (6) configured to hold a support (1) on which a semiconductor element (3A) is disposed,

wherein the first punch (7A) approaches the carrier (6) from a first side (z1) in a first direction (z) through relative movement, and the second punch (7B) approaches the carrier (6) from a second side (z2) in the first direction (z) through relative movement, the first punch (7A) and the second punch (7B) thereby performing bonding of the support (1) and the semiconductor element (3A),

the semiconductor element (3A) is positioned on the second side (z2) in the first direction (z) with respect to the support (1) and includes a first ferromagnetic layer (311), and
the carrier (6) includes a magnet section (63) positioned on the first side (z1) in the first direction (z) with respect to the support (1).

### Clause 2

The semiconductor module manufacturing device (A1) according to Clause 1, wherein the magnet section (63) comprises a permanent magnet.

### Clause 3

The semiconductor module manufacturing device (A2) according to Clause 1, wherein the magnet section (63) comprises an electromagnet.

### Clause 4

The semiconductor module manufacturing device (A1) according to any one of Clauses 1 to 3, wherein the first punch (7A) is made of a non-magnetic material.

### Clause 5

The semiconductor module manufacturing device (A1) according to any one of Clauses 1 to 4, wherein the second punch (7B) is made of a non-magnetic material.

### Clause 6

The semiconductor module manufacturing device (A1) according to any one of Clauses 1 to 5, wherein the magnet section (63) contacts the support (1) when the bonding is performed.

### Clause 7

The semiconductor module manufacturing device (A11) according to any one of Clauses 1 to 5, wherein the magnet section (63) does not contact the support (1) when the bonding is performed.

### Clause 8

The semiconductor module manufacturing device (A11) according to Clause 7, wherein the carrier (6) includes a non-magnetic cover (64) configured to be interposed between the magnet section (63) and the support (1) when the bonding is performed.

### Clause 9

The semiconductor module manufacturing device (A12) according to any one of Clauses 1 to 8, wherein the carrier (6) includes a ferromagnetic cover (65) configured to be interposed between the magnet section (63) and the first punch (7A) when the bonding is performed.

### Clause 10

A semiconductor module manufacturing method, the method comprising:

holding a support (1) and a semiconductor element (3A) by a carrier (6); and

performing bonding of the support (1) and the semiconductor element (3A) by causing, through relative movement, a first punch (7A) and a second punch (7B) to approach the support (1) and the semiconductor element (3A) held by the carrier (6), the first punch (7A) approaching from a first side (z2) in a first direction (z), the second punch (7B) approaching from a second side (z2) in the first direction (z);

wherein holding the support (1) and the semiconductor element (3A) by the carrier (6) includes placing the semiconductor element (3A) on the second side (z2) in the first direction (z) with respect to the support (1),

the semiconductor element (3A) includes a first ferromagnetic layer (311), and

the carrier (6) includes a magnet section (63) positioned on the first side (z1) in the first direction (z) with respect to the support (1).

### Clause 11

The method according to Clause 10, wherein the magnet section (63) comprises a permanent magnet.

### Clause 12

The method according to Clause 10, wherein the magnet section (63) comprises an electromagnet.

### Clause 13

The method according to Clause 12, wherein the magnet section (63) exerts a magnetic force when the bonding is performed.

### Clause 14

The method according to any one of Clauses 10 to 13, wherein the first punch (7A) is made of a non-magnetic material.

### Clause 15

The method according to any one of Clauses 10 to 14, wherein the second punch (7B) is made of a non-magnetic material.

### REFERENCE NUMERALS

A1, A11, A12, A2: semiconductor module manufacturing device 1: support
2A and 2B: first bonding sheet 3A and 3B: semiconductor element
6: carrier 7A: first punch
7B: second punch 10: insulating layer
11: first metal layer 12A, 12B: second metal layer
13A, 13B: third metal layer 14A, 14B: second bonding sheet
20: main body layer 21: second ferromagnetic layer
22: third bonding layer 30: element body
31: drain electrode 32: source electrode
33: gate electrode 34: source-sense electrode
41A: positive input terminal 41B: output terminal
41C: negative input terminal 41D: control terminal
41E: control terminal 42A: first wire
42B: second wire 42C: third wire
42D: fourth wire 43: sealing resin
61: frame portion 62: support portion
63: magnet section 64: non-magnetic cover
65: ferromagnetic cover 68: magnet controller
70: base 71: pin
89: protective sheet 120: main body layer
122: third bonding layer 310: main body layer
311: first ferromagnetic layer 312: first bonding layer
610: opening 910: on-board charger
920: storage battery 930: drive system
931: inverter 932: drive source
B1: semiconductor module C1: vehicle
Mf, Mf1: magnetic force x: second direction
y: third direction z: first direction

1. A semiconductor module manufacturing device comprising:
a first punch;
a second punch; and
a carrier configured to hold a support on which a semiconductor element is disposed,
wherein the first punch approaches the carrier from a first side in a first direction through relative movement, and the second punch approaches the carrier from a second side in the first direction through relative movement, the first punch and the second punch thereby performing bonding of the support and the semiconductor element,
the semiconductor element is positioned on the second side in the first direction with respect to the support and includes a first ferromagnetic layer, and
the carrier includes a magnet section positioned on the first side in the first direction with respect to the support.

2. The semiconductor module manufacturing device according to claim 1, wherein the magnet section comprises a permanent magnet.

3. The semiconductor module manufacturing device according to claim 1, wherein the magnet section comprises an electromagnet.

4. The semiconductor module manufacturing device according to claim 1, wherein the first punch is made of a non-magnetic material.

5. The semiconductor module manufacturing device according to claim 1, wherein the second punch is made of a non-magnetic material.

6. The semiconductor module manufacturing device according to claim 1, wherein the magnet section contacts the support when the bonding is performed.

7. The semiconductor module manufacturing device according to claim 1, wherein the magnet section does not contact the support when the bonding is performed.

8. The semiconductor module manufacturing device according to claim 7, wherein the carrier includes a non-magnetic cover configured to be interposed between the magnet section and the support when the bonding is performed.

9. The semiconductor module manufacturing device according to claim 1, wherein the carrier includes a ferromagnetic cover configured to be interposed between the magnet section and the first punch when the bonding is performed.

10. A semiconductor module manufacturing method, the method comprising:
holding a support and a semiconductor element by a carrier; and
performing bonding of the support and the semiconductor element by causing, through relative movement, a first punch and a second punch to approach the support and the semiconductor element held by the carrier, the first punch approaching from a first side in a first direction, the second punch approaching from a second side in the first direction;
wherein holding the support and the semiconductor element by the carrier includes placing the semiconductor element on the second side in the first direction with respect to the support,
the semiconductor element includes a first ferromagnetic layer, and
the carrier includes a magnet section positioned on the first side in the first direction with respect to the support.

11. The method according to claim 10, wherein the magnet section comprises a permanent magnet.

12. The method according to claim 10, wherein the magnet section comprises an electromagnet.

13. The method according to claim 12, wherein the magnet section exerts a magnetic force when the bonding is performed.

14. The method according to claim 10, wherein the first punch is made of a non-magnetic material.

15. The method according to claim 10, wherein the second punch is made of a non-magnetic material.
